(19) United States
(12) Patent Application Publication
(10) Pub. No.: US 2022/0064813 A1
(43) Pub. Date: Mar. 3, 2022

(54) METHOD OF ELECTROPLATING STRESS-FREE COPPER FILM

(71) Applicants: SUZHOU SHINHAO MATERIALS LLC, Suzhou (CN); UMICORE GALVANOTECHIK GMBH, Schwaebisch Gmuend (DE)

(72) Inventors: Yun ZHANG, Suzhou (CN); Xingxing ZHANG, Suzhou (CN); Volker WOHLFARTH, Eschach (DE); Jing WANG, Suzhou (CN); Peipei DONG, Suzhou (CN); Wei ZHAO, Suzhou (CN)

(21) Appl. No.: 17/166,104

(22) Filed: Feb. 3, 2021

Related U.S. Application Data
(63) Continuation of application No. PCT/CN2020/111991, filed on Aug. 28, 2020.

(51) Int. Cl. C25D 3/38; C25D 17/00; H05K 3/24

(52) U.S. Cl. CPC C25D 3/38; H05K 3/241; C25D 17/001

(57) ABSTRACT

A method of electroplating a stress-free copper film on a substrate includes: providing the substrate; providing an electroplating bath that includes a copper salt, an acid, a leveler, a chlorine compound, an accelerator, a suppressor; and water; heating the electroplating bath to 25 to 60° C.; and electroplating the substrate in the electroplating bath to form the stress-free copper film while maintaining the electroplating bath at 25 to 60° C. The leveler is an organic compound containing an amine group. The method further includes annealing the stress-free copper film at 60-260° C. for 0.5 to 2 hours, or at 60-120° C. for 0.5 to 2 hours. A stress-free electroplated copper film is also disclosed.

### FIELD OF THE INVENTION

The present invention relates to a method of electroplating a stress-free copper film and the stress-free copper film prepared by the method.

### BACKGROUND OF THE INVENTION

Copper is used ubiquitously in the electronics industry as an electrical and thermal conductor. It is found in almost all electrical devices today and serves the function for electrical conductivity or as a heat sink to take away heat that is generated from the heat generating sources such as CPUs. In today's microelectronics manufacturing, electroplating is a method of choice to make thin or thick copper films inside various semiconductor and conductor devices. This is especially true for PCB and wafer plating, where copper is electrodeposited onto a PCB board or onto a wafer. In recent years, copper is plated onto a “reconstituted wafer” in so called fan-out wafer level packaging (FOWLP) or it is plated onto large substrate panels in so called fan-out panel level packaging (FOPLP). The move from a wafer to a panel is mostly for cost reduction purposes, as a panel size in production today is about 5 times larger than a 12-inch wafer. This means roughly five times more dies or units could be manufactured with panel level packaging. However, larger panel makes certain issues more problematic than on a wafer. One such an issue is the intrinsic stress of electroplated copper.

Intrinsic or internal stress of electrodeposited metals is a well-known phenomenon caused by imperfections in the electroplated crystal structure. After electroplating such imperfections seek to self-correct and this induces a force on the deposit to either contract (tensile stress) or expand (compressive stress). As shown in FIG. 10, when there is a tensile stress, an electroplated copper film on a substrate tends to contract in order to relieve the stress; and when there is a compressive stress, an electroplated copper film on a substrate tends to expand in order to relieve the stress. This stress and its relief can be problematic. For example, when electroplating is predominantly on one side of a substrate it can lead to curling, bowing and warping of the substrate depending on the flexibility of the substrate and the magnitude of the stress. Stress can lead to poor adhesion of the deposit to the substrate resulting in blistering, peeling or cracking. This is especially the case for difficult to adhere substrates, such as semiconductor wafers or those with relatively smooth surface topography. In general, the magnitude of stress is proportional to deposit thickness thus it can be problematic where thicker deposits are required or indeed may limit the achievable deposit thickness.

Most metals including copper when is plated from an acid bath produce internal stress. Commercial acid copper plating baths typically include copper sulfate, sulfuric acid and chloride as so-called virgin makeup solution (VMS). In addition, proprietary additives, such as suppressors, accelerators and levelers, are added into the plating bath to make it a functional bath. The copper film resulted from such a bath typically is bright in appearance and has either tensile stress or compressive stress after plating. It is well-known that such a copper film would undergo grain growth at room temperature after plating or at some elevated temperatures, resulting a change in stress during the process. This is undesirable for two reasons: one, there is intrinsic stress; second, the intrinsic stress changes after plating, indicating process unpredictability. Furthermore, the stress of the copper film changes during bath aging as well, again this results in process unpredictability. Because of this, manufacturers would have to use a much thicker substrate (silicon or organic substrate) which reduces thermal conductivity of the device, or plate a thinner copper which reduces electrical conductance of the device.

On the other hand, advanced packaging calls for thinner package, higher current density or current carrying ability. This demand could only be best met with a stress-free copper. In addition, this stress-free copper ideally should stay stress-free during the subsequent manufacturing steps after plating. Furthermore, the electroplating bath also needs to produce copper deposit that meets other critical plating performance criteria for advanced packaging such as WID (within die) uniformity, WIW (within wafer) uniformity, and WIF (within feature) uniformity at current densities ranging from 1 to 40 ASD.

Currently, there are no methods available to produce stress-free copper film. There are also no stress-free copper films available. There is a need for a method of making a stress-free copper film under typical manufacturing process conditions and stay unchanged after the subsequent steps and stress-free copper film produced by the method.

It is important to point out that little is understood scientifically as what causes the internal stress in electroplated copper and how to reduce it or remove it all together despite of its importance.

The copper plating process used in advanced packaging typically is a bright copper process that comprises an accelerator, a suppressor and a leveler, or a so-called three additive system. Detailed description of a copper plating process and explanation of the role of each additive can be found in “Modern Electroplating”. It is a general understanding and known factor that among the three additives, leveler is the deciding factor concerning within die uniformity, which plays a critical role in overall plating performance. It is our discovery that it also plays a critical role in generating stress-free copper deposit

U.S. Pat. No. 9,494,886 B2 teaches that an acid copper plating bath comprising an accelerator and a suppressor could produce a matte finish with low stress, and such stress would not change after storing for 44 days. However, a copper deposit resulted from a two additive system would not have been able to meet the uniformity requirement for advanced packaging. In addition, its operating current density needs to be obtained by first performing a Hull cell experiment to determine its value, which makes it not practical for manufacturing. Furthermore, the maximum current density range appears to be at or around 4 ASD, which is too low in plating speed. This severely limits its applicability for thick copper plating.

U.S. Pat. No. 9,494,886 B2 also teaches that a conventional acid copper plating bath comprising three additives (an accelerator, a suppressor and a leveler) would produce a bright film, and a small grain size compared to the matter finish mentioned above. Upon standing for two days and two weeks respectively, the grain size grows significantly resulting in change in internal stress which in not desirable.

It is important to point out that the acid copper plating process and the method of producing stress-free copper are not limited to FOWLP and FOPLP, it is applicable to situations that a thick copper film needs to be generated on any thin substrates such as silicon, PCB, glass, ceramic, metals or composite structures made among them.

### SUMMARY OF THE INVENTION

It is to be understood that both the foregoing general description and the following detailed description are exemplary and explanatory and are intended to provide further explanation of the invention as claimed.

In one embodiment, a method of electroplating a stress-free copper film on a substrate includes: providing the substrate; providing an electroplating bath that includes a copper salt, an acid, a leveler, a chlorine compound, an accelerator, a suppressor; and water; heating the electroplating bath to 25 to 60° C.; and electroplating the substrate in the electroplating bath to form the stress-free copper film while maintaining the electroplating bath at 25 to 60° C. The leveler is an organic compound.

In another embodiment, the electroplating bath is heated to 30 to 55° C., and the electroplating bath is maintained at 30 to 55° C. for the electroplating; the electroplating bath is heated to 35 to 50° C., and the electroplating bath is maintained at 35 to 50° C. for the electroplating; the electroplating bath is heated to 35 to 45° C., and the electroplating bath is maintained at 35 to 45° C. for the electroplating; or the electroplating bath is heated to 40 to 45° C., and the electroplating bath is maintained at 40 to 45° C. for the electroplating.

In another embodiment, the electroplating is conducted at a current density of 2-20 A/dm²; at a current density of 3-15 A/dm²; or at a current density of 5-10 A/dm².

In another embodiment, the copper salt is copper sulfate and has a Cu⁺ concentration of 25-75 g/L; the acid is sulfuric acid and has a concentration of 75-125 g/L; the chlorine compound is hydrochloride and has a Cl⁻ concentration of 25-75 ppm; the accelerator has a concentration of 3-30 mg/L; and the suppressor has a concentration of 500-1500 mg/L; and leveler has a concentration of 5-100 mg/L.

In another embodiment, the accelerator is selected from the group consisting of 3,3′-dithiobis(1-propane-sulfonic acid), 3-mercapto-1-propane sulfonic acid, ethylenedithiodipropyl sulfonic acid, bis-(ω-sulfobutyl)-disulfide, methyl-(ω-sulfopropyl)-disulfide, N,N-dimethyldithiocarbamic acid (3-sulfopropyl) ester, (O-ethyldithiocarbonato)-S-(3-sulfopropyl)-ester, 3-[(amino-iminomethyl)-thiol]-1-propanesulfonic acid, 3-(2-benzylthiazolylthio)-1-propanesulfonic acid, bis-(sulfopropyl)-disulfide, and alkali metal salts thereof.

In another embodiment, the suppressor is selected from the group consisting of polyoxyalkylene glycol, carboxymethylcellulose, nonylphenolpolyglycol ether, octandiolbis-(polyalkylene glycolether), octanolpolyalkylene glycolether, oleic acidpolyglycol ester, polyethylenepropylene glycol, polyethylene glycol, polyethylene glycoldimethylether, polyoxypropylene glycol, polypropylene glycol, polyvinylalcohol, stearic acidpolyglycol ester and stearyl alcoholpolyglycol ether.

In another embodiment, the leveler is selected from the group consisting of 1-(2-hydroxyethyl)-2-imidazolidinethione, 4-mercaptopyridine, 2-mercaptothiazoline, ethylene thiourea, thiourea, alkylated polyalkyleneimine, poly[bis(2-chloroethyl) ether-alt-1,3-bis[3-(dimethylamino)propyl]urea], poly(diallyldimethylammonium chloride), L-2-amino-3-ureidopropionic acid, poly(ethyleneimine)

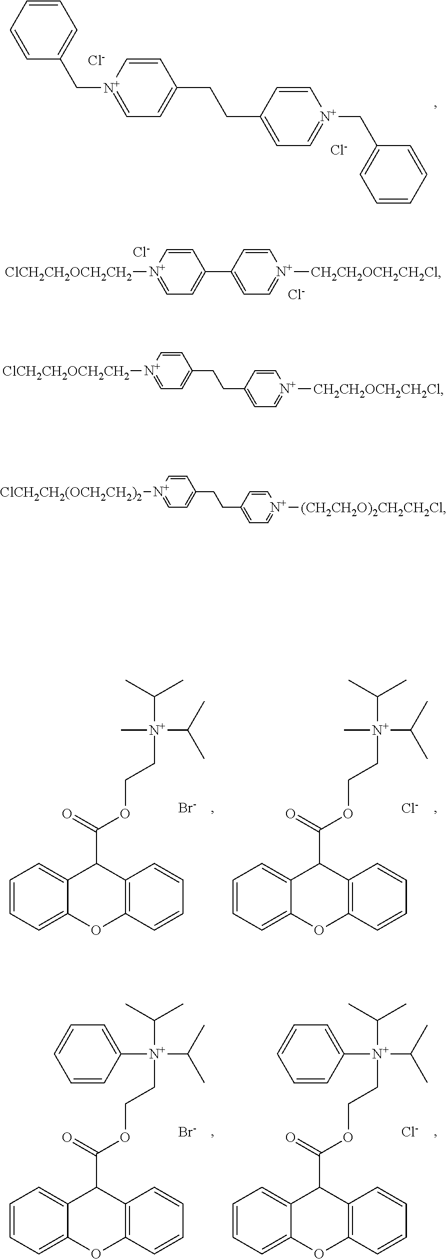

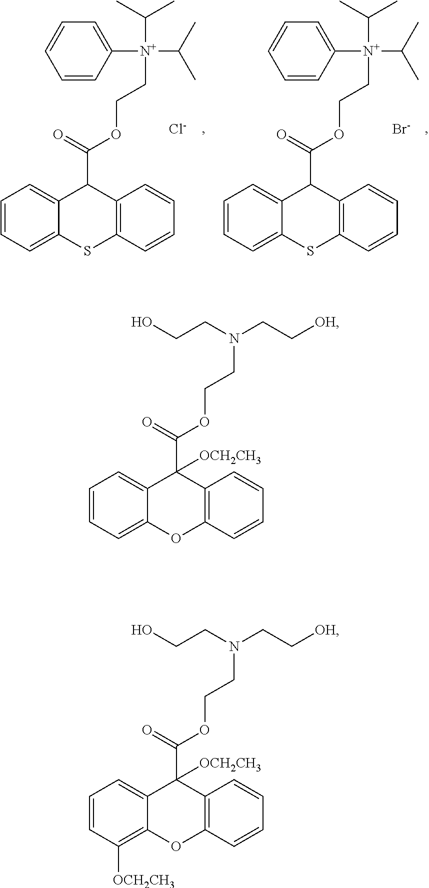 [SMILES: CC(C)[N+](CCOC(=O)C1c2ccccc2Sc2ccccc21)(c1ccccc1)C(C)C ; [Cl-] ; CC(C)[N+](CCOC(=O)C1c2ccccc2Sc2ccccc21)(c1ccccc1)C(C)C ; [Br-] ; CCOC1(C(=O)OCCN(CCO)CCO)c2ccccc2Oc2ccccc21 ; CCOc1cccc2c1Oc1ccccc1C2(OCC)C(=O)OCCN(CCO)CCO]

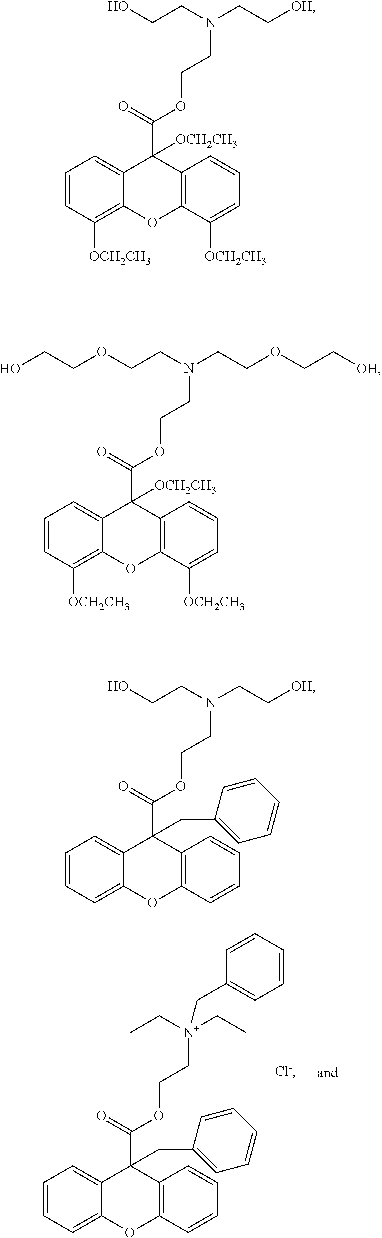 [SMILES: CCOc1cccc2c1Oc1c(OCC)cccc1C2(OCC)C(=O)OCCN(CCO)CCO ; CCOc1cccc2c1Oc1c(OCC)cccc1C2(OCC)C(=O)OCCN(CCOCCO)CCOCCO ; O=C(OCCN(CCO)CCO)C1(Cc2ccccc2)c2ccccc2Oc2ccccc21 ; CC[N+](CC)(CCOC(=O)C1(Cc2ccccc2)c2ccccc2Oc2ccccc21)Cc1ccccc1]

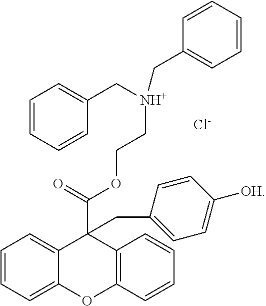 [SMILES: O=C(OCC[NH+](Cc1ccccc1)Cc1ccccc1)C1(Cc2ccc(O)cc2)c2ccccc2Oc2ccccc21 ; [Cl-]]

In another embodiment, the method further includes: annealing the stress-free copper film at 60-260° C. for 0.5 to 2 hours, or at 60-120° C. for 0.5 to 2 hours.

In another embodiment, the method further includes: stirring the electroplating bath at an agitation of 100-1400 rpm or its corresponding double layer thickness while electroplating the substrate in the electroplating bath to form the stress-free copper film.

In one embodiment, a stress-free electroplated copper film comprising: a thickness of 2 to 200 μm; a first internal stress of about −0.08 to 0.20 MPa, the first internal stress being measured within 1 hour after electroplating the stress-free electroplated copper film on a substrate; a second internal stress of about 0.08 to 0.12 MPa, the second internal stress being measured 24 hours after electroplating or after electroplating and annealed at 60 to 120° C. for 0.5 to 2 hours; an impurity of 20 to 120 ppm; and an X-ray powder diffraction pattern having an I(111):I(200):I(220) intensity ratio of about 100:9.5:3.7 or 27:2.5:1.

In another embodiment, the stress-free electroplated copper film further includes: a third internal stress of about 0.08 to 0.12 MPa, the third internal stress being measured 72 hours after electroplating or annealing.

In one embodiment, a stress-free electroplated copper film includes: a thickness of 2 to 200 μm; a first internal stress of about −4.0 to 4.0 MPa, the first internal stress being measured within 1 hour after electroplating the stress-free electroplated copper film on a substrate; a second internal stress of about 0.08 to 0.12 MPa, the second internal stress being measured after electroplating and annealed at 60-120° C. for 0.5 to 2 hours; an impurity of 1 to 4 ppm; and an X-ray powder diffraction pattern having an I(111):I(200):I(220) intensity ratio of about 100:7:7 or 14.3:1:1.

In another embodiment, the stress-free electroplated copper film further includes: a third internal stress of about 0.08 to 0.12 MPa, the third internal stress being measured 72 hours after annealing.

In another embodiment, the impurity in the stress-free electroplated copper film includes carbon, oxygen, nitrogen, sulfur, and chlorine.

In another embodiment, the thickness of the stress-free electroplated copper film is 10 to 50 μm.

In another embodiment, the stress-free electroplated copper film has a resistivity of 1.70 to 2.20 μOhM·cm.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 shows the internal stress of electroplated copper film of example 1.

FIG. 2 shows the internal stress of electroplated copper film of example 2.

FIG. 3 shows the grain structure of electroplated copper film of example 1.

FIG. 4 shows the grain structure of electroplated copper film of example 2.

FIG. 5 shows the X-ray diffraction pattern of the electroplated copper film of example 1.

FIG. 6 shows the X-ray diffraction pattern of the electroplated copper film of example 2.

FIG. 7 shows the flatness and uniformity of the electroplated copper film of example 1.

FIG. 8 shows the electroplating temperature effect on the electroplated copper film of example 1.

FIG. 9 shows the electroplating temperature effect on the electroplated copper film of example 2.

FIG. 10 shows an electroplated copper film on a substrate with tensile stress, and an electroplated copper film on a substrate with compressive stress.

### DETAILED DESCRIPTION OF THE ILLUSTRATED EMBODIMENTS

Reference will now be made in detail to embodiments of the present invention, example of which is illustrated in the accompanying drawings.

This invention discloses a copper electroplating bath that contains a three-additive system and a method of producing a matte or a bright copper film with the copper electroplating bath. In addition, this electroplating bath when operated under certain conditions could produce a stress-free copper film.

In one embodiment, an electroplating bath composition contains a copper salt, an acid, a chloride compound, an accelerator, a leveler and a suppressor.

The copper salt can be copper sulfate and the acid can be sulfuric acid. The concentration of copper ion and acid may vary over wide limits; for example, from about 4 to 70 g/L copper and from about 2 to about 225 g/L sulfuric acid. In this regard the methods of the invention are suitable for use in distinct acid/copper concentration ranges, such as high acid/low copper systems, in low acid/high copper systems, and mid acid/high copper systems. In high acid/low copper systems, the copper ion concentration can be on the order of 4 g/L to on the order of 30 g/L; and the acid concentration may be sulfuric acid in an amount greater than about 100 g/L up to 225 g/L. In exemplary high acid low copper system, the copper ion concentration is about 17 g/L, where the sulfuric acid concentration is about 180 g/L. In some low acid/high copper systems, the copper ion concentration can be between 35 g/L to about 65 g/L, such as between 38 g/L and about 50 g/L. 35 g/L copper ion corresponds to about 140 g/L CuSO₄.5H₂O, copper sulfate pentahydrate. In some low acid high copper systems, the copper ion concentration can be between 30 to 60 g/L, such as between 40 g/L to about 50 g/L. The acid concentration in these systems is preferably less than about 100 g/L.

In other embodiments, the copper source can be copper methanesulfonate and the acid can be methanesulfonic acid. The use of copper mathanesulfonate as the copper source allows for greater concentrations of copper ions in the electrolytic copper deposition chemistries in comparison to other copper ion sources. Accordingly, the source of copper ion may be added to achieve copper ion concentrations greater than about 80 g/L, greater than about 90 g/L, or even greater than about 100 g/L, such as, for example about 110 g/L. Preferably, the copper methanesulfonate is added to achieve a copper ion concentration between about 30 g/L to about 100 g/L, such as between about 40 g/L and about 60 g/L. High copper concentrations enabled by the used of copper methanesulfonate is thought to be one method for alleviating the mass transfer problem, i.e., local depletion of copper ions particularly at the bottom of deep features. High copper concentrations in the bulk solution contribute to a step copper concentration gradient that enhances diffusion of copper into the features.

When copper methane sulfonate is used, it is preferred to use methane sulfonic acid for acid pH adjustment. This avoids the introduction of unnecessary anions into the electrolytic deposition chemistry. When methane sulfonic acid is added, its concentration may be between about 1 ml/L to about 400 ml/L.

Chloride ion or bromide ion may also be used in the bath at a level up to about 200 mg/L (about 200 ppm), preferably from about 10 mg/L to about 90 mg/L (about 10 to 90 ppm), such as about 50 mg/L (about 50 ppm). Chloride ion or bromide ion is added in these concentration ranges to enhance the function of other bath additives. In particular, it has been discovered that the addition of chloride ion or bromide ion enhances the effectiveness of a leveler. Chloride ions are added using HCl. Bromide ions are added using HBr.

A large variety of additives may typically be used in the bath to provide desired surface finishes and metallurgies for the plated copper metal. Usually more than one additive is used to achieve desired functions. At least two or three additives are generally used to initiate good copper deposition as well as to produce desirable surface morphology with good conformal plating characteristics. Additional additives (usually organic additives) include wetter, grain refiners and secondary brighteners and polarizers for the suppression of dendritic growth, improved uniformity and defect reduction.

In some embodiments, the accelerator is selected from the group consisting of 3,3′-dithiobis(1-propane-sulfonic acid), 3-mercapto-1-propane sulfonic acid, ethylenedithiodipropyl sulfonic acid, bis-(ω-sulfobutyl)-disulfide, methyl-(ω-sulfopropyl)-disulfide, N,N-dimethyldithiocarbamic acid (3-sulfopropyl) ester, (O-ethyldithiocarbonato)-S-(3-sulfopropyl)-ester, 3-[(amino-iminomethyl)-thiol]-1-propanesulfonic acid, 3-(2-benzylthiazolylthio)-1-propanesulfonic acid, bis-(sulfopropyl)-disulfide, and alkali metal salts thereof; and

In some embodiments, the suppressor is selected from the group consisting of polyoxyalkylene glycol, carboxymethylcellulose, nonylphenolpolyglycol ether, octandiolbis-(polyalkylene glycolether), octanolpolyalkylene glycolether, oleic acidpolyglycol ester, polyethylenepropylene glycol, polyethylene glycol, polyethylene glycoldimethylether, polyoxypropylene glycol, polypropylene glycol, polyvinylalcohol, stearic acidpolyglycol ester and stearyl alcoholpolyglycol ether.

In some embodiments, the leveler is selected from the group consisting of 1-(2-hydroxyethyl)-2-imidazolidinethione, 4-mercaptopyridine, 2-mercaptothiazoline, ethylene thiourea, thiourea, alkylated polyalkyleneimine, poly[bis(2-chloroethyl) ether-alt-1,3-bis[3-(dimethylamino)propyl]urea], poly(diallyldimethylammonium chloride), L-2-amino-3-ureidopropionic acid, poly(ethyleneimine),

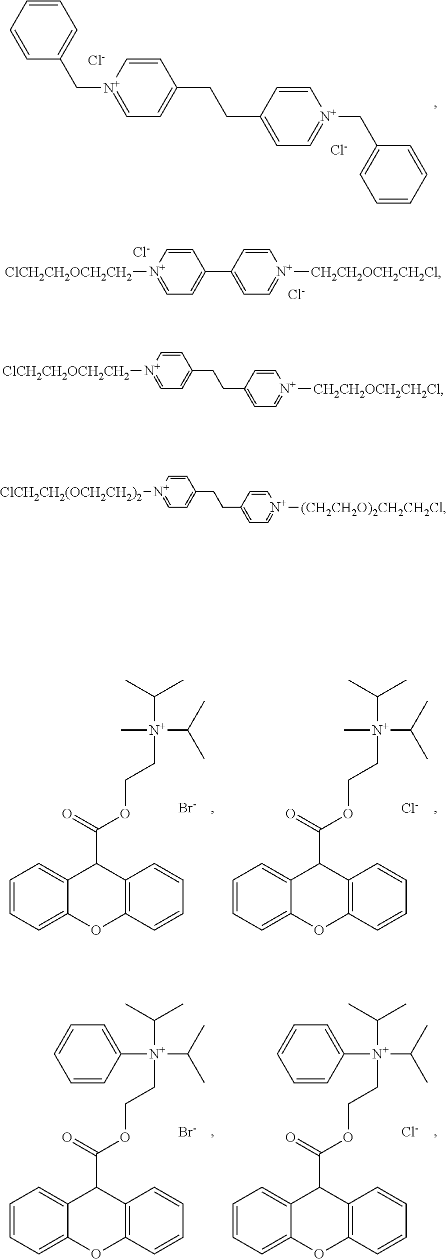

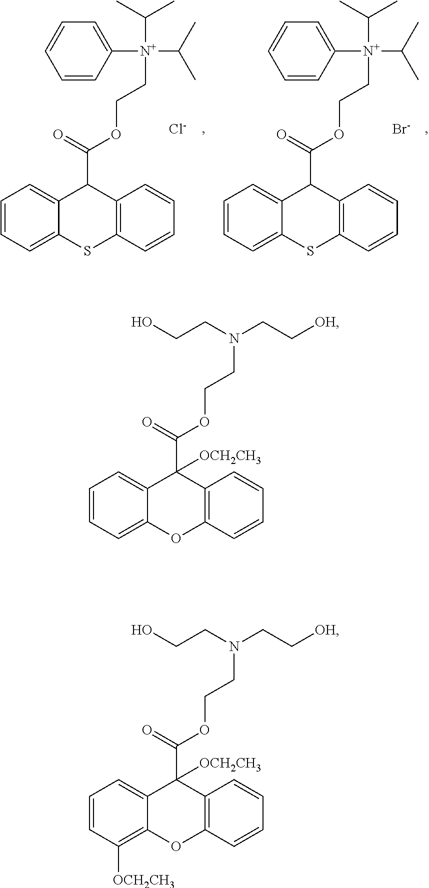 [SMILES: CC(C)[N+](CCOC(=O)C1c2ccccc2Sc2ccccc21)(c1ccccc1)C(C)C ; [Cl-] ; CC(C)[N+](CCOC(=O)C1c2ccccc2Sc2ccccc21)(c1ccccc1)C(C)C ; [Br-] ; CCOC1(C(=O)OCCN(CCO)CCO)c2ccccc2Oc2ccccc21 ; CCOc1cccc2c1Oc1ccccc1C2(OCC)C(=O)OCCN(CCO)CCO]

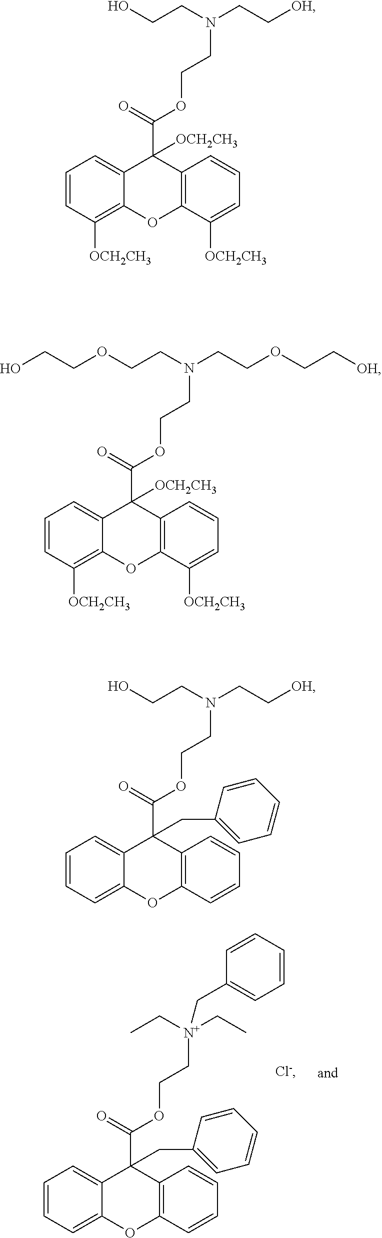 [SMILES: CCOc1cccc2c1Oc1c(OCC)cccc1C2(OCC)C(=O)OCCN(CCO)CCO ; CCOc1cccc2c1Oc1c(OCC)cccc1C2(OCC)C(=O)OCCN(CCOCCO)CCOCCO ; O=C(OCCN(CCO)CCO)C1(Cc2ccccc2)c2ccccc2Oc2ccccc21 ; CC[N+](CC)(CCOC(=O)C1(Cc2ccccc2)c2ccccc2Oc2ccccc21)Cc1ccccc1]

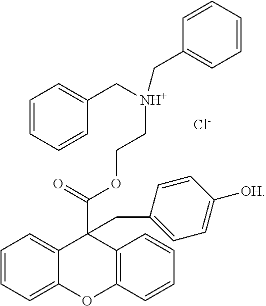 [SMILES: O=C(OCC[NH+](Cc1ccccc1)Cc1ccccc1)C1(Cc2ccc(O)cc2)c2ccccc2Oc2ccccc21 ; [Cl-]]

Plating equipment for electroplating semiconductor substrates is well known. Electroplating equipment includes an electroplating tank which holds an electroplating bath and which is made of a suitable material such as plastic or other material inert to the electroplating bath. The tank may be cylindrical, especially for wafer plating. A cathode is horizontally disposed at the upper part of the tank and may be any type of substrate such as a silicon wafer having openings such as lines and vias. The wafer substrate is typically coated first with barrier layer, which may be titanium nitride, tantalum, tantalum nitride, or ruthenium to inhibit copper diffusion, and next with a seed layer of copper or other metal to initiate copper electrodeposition. A copper seed layer may be applied by chemical vapor deposition (CVD), physical vapor deposition (PVD), or the like. The copper seed layer may also be electroless copper. An anode is also preferably circular for wafer plating and is horizontally disposed at the lower part of tank forming a space between the anode and the cathode. The anode is typically a soluble anode such as copper metal. It could also be insoluble anode or dimensional stable anode. For panel plating, the anode is preferably of a rectangular shape. The anode can be a soluble one or an insoluble one.

The electroplating bath additives can be used in combination with membrane technology being developed by various plating tool manufacturers. In this system, the anode may be isolated from the organic bath additives by a membrane. The purpose of the separation of the anode and the organic bath additives is to minimize the oxidation of the organic bath additives on the anode surface.

In some embodiment, the electroplating bath can be used as a “drop-in” replacement of existing copper plating baths.

The cathode substrate and anode are electrically connected by wiring and, respectively, to a rectifier (power supply). The cathode substrate for direct or pulse current has a net negative charge so that copper ions in the solution are reduced at the cathode substrate forming plated copper metal on the cathode surface. An oxidation reaction takes place at the anode. The cathode and anode may be horizontally or vertically disposed in the tank.

During operation of the electroplating bath, a pulse current, direct current, reverse periodic current, or other suitable current may be employed. The temperature of the electroplating bath can be maintained using a heater/cooler whereby electroplating bath is removed from the holding tank and flows through the heater/cooler and it is recycled to the holding tank.

In some embodiments, the electroplating bath can be heated and maintained at temperatures from room temperature to 65° C., from 25 to 60° C., from 30 to 55° C., from 35 to 50° C., from 40 to 45° C., at 40° C., at 41° C., at 42° C., at 43° C., at 44° C., or at 45° C., for conducting electroplating.

The electrical current density can be from 1 A/dm² (ASD) to 40 A/dm², from 2 A/dm² to 20 A/dm², from 3 A/dm² to 15 A/dm², or from 5 A/dm² to 10 A/dm². It is preferred to use an anode to cathode ratio of 1:1, but this may also vary widely from about 1:4 to about 4:1. The process also uses mixing in the electrolytic plating tank which may be supplied by agitation or preferably by the circulating flow of recycle electrolytic solution through the tank.

In some embodiments, the electroplating can be conducted on various substrates such as glass, organic polymer, silicon, ceramics, and metals.

After electroplating, the copper film can be annealed at temperatures from 60 to 275° C., from 60 to 180° C., from 60 to 120° C., at 60° C., at 65° C., at 70° C., at 75° C., at 80° C., at 85° C., at 90° C., at 95° C., at 100° C., at 105° C., at 110° C., at 115° C., or at 120° C., for from 0.5 to 2 hours. For example, the electroplated copper film can be annealed at 60° C. for 0.5 hour.

In some embodiments, the electroplated copper film is of high purity and density, is of high smoothness and flat surface topography.

In some embodiments, the electroplated copper film is of a bright appearance.

In some embodiments, the electroplated copper film is of a matte appearance.

In some embodiments, the electroplated copper film is internal stress free. The phrase “internal stress free” means the internal stress is about −4.0 to 4.0 MPa, preferably, −0.08 to 0.20 MPa, more preferably, 0.08 to 0.12 MPa. The term “about” means in the range of +20% to −20% of a value, +10% to −10% of the value, or +5% to −5% of the value.

In some embodiments, the internal stress of the electroplated copper film can be measured at three different times. First measurement is conducted immediately after electroplating, usually within one hour after electroplating. Second measurement is conducted 24 hours after electroplating. Before the second measurement, the electroplated copper film can be optionally annealed at 60-260° C. for 0.5 to 2 hours or at 60-120° C. for 0.5 to 2 hours. Third measurement is conducted 72 hours after electroplating or annealing.

In some embodiments, the electroplated copper film has an internal stress of about −0.08 to 0.20 MPa at the first measurement, an internal stress of about 0.08 to 0.12 MPa at the second measurement, and an internal stress of about 0.08 to 0.12 MPa at the third measurement.

In some embodiments, the electroplated copper film has an impurity of 20 to 120 ppm, preferably, 30 to 100 ppm, and an X-ray powder diffraction pattern having an I(111):I(200):I(220) intensity ratio of about 100:9.5:3.7 or 27:2.5:1.

In some embodiments, the electroplated copper film has an internal stress of about −4.0 to 4.0 MPa at the first measurement, an internal stress of about 0.08 to 0.12 MPa after being annealed at 60-260° C. for 0.5 to 2 hours at the second measurement, and an internal stress of about 0.08 to 0.12 MPa at the third measurement.

In some embodiments, the electroplated copper film has an impurity of 1 to 4 ppm, preferably, 2-4 ppm, and an X-ray powder diffraction pattern having an I(111):I(200) I(220) intensity ratio of about 100:7:7 or 14.3:1:1.

### EXAMPLES

The following non-limiting examples are provided to further illustrate the present invention. While the leveler of present invention can be used in electroplating of metals such as copper, tin, nickel, zinc, silver, gold, palladium, platinum, and iridium, only electrolytic copper plating chemistries are described below.

### Example 1

An electrolytic copper plating composition of the invention was prepared having the following components and concentrations:

The electrolytic copper deposition chemistry and plating conditions were prepared according to the instructions of Table 1 for example 1.

TABLE 1

| Consideration | Example | Range |
|---|---|---|
| Copper, g/L | 50 | 25 to 75 |
| Sulfuric acid. g/L | 100 | 75 to 125 |
| Chloride, ppm | 50 | 25 to 75 |
| Suppressor, ppm | 500 | 500 to 1500 |
| Leveler, ppm | 70 | 5 to 100 |
| Accelerator, ppm | 10 | 3 to 30 |
| Plating Temperature, ° C. | 40 | 25 to 65 |
| Plating rate, ASD | 5 | 2 to 20 |
| Agitation speed, RPM | 200 | 100 to 400 |

The chlorine compound is hydrochloric acid. The suppressor is polyoxyalkylene glycol and its analogue or equivalent. The accelerator is 3,3′-dithiobis(1-propane-sulfonic acid) and its analogue or equivalent. The leveler is

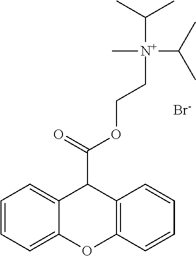 [SMILES: CC(C)[N+](C)(CCOC(=O)C1c2ccccc2Oc2ccccc21)C(C)C ; [Br-]]

and its analogue or equivalent.

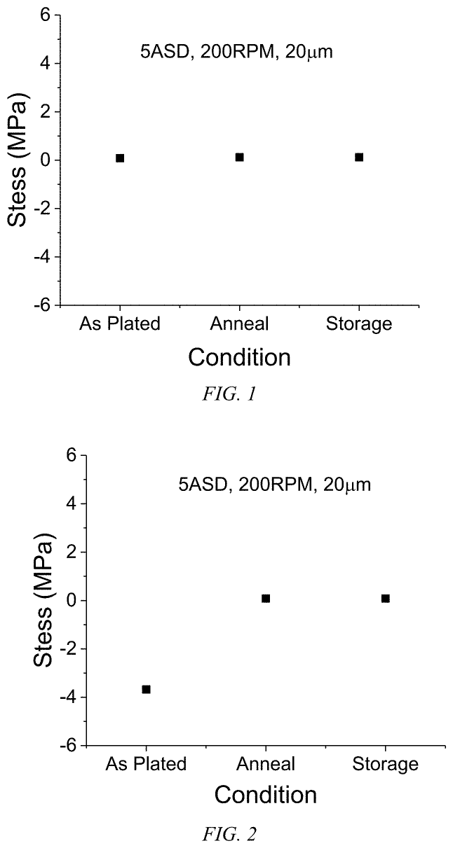

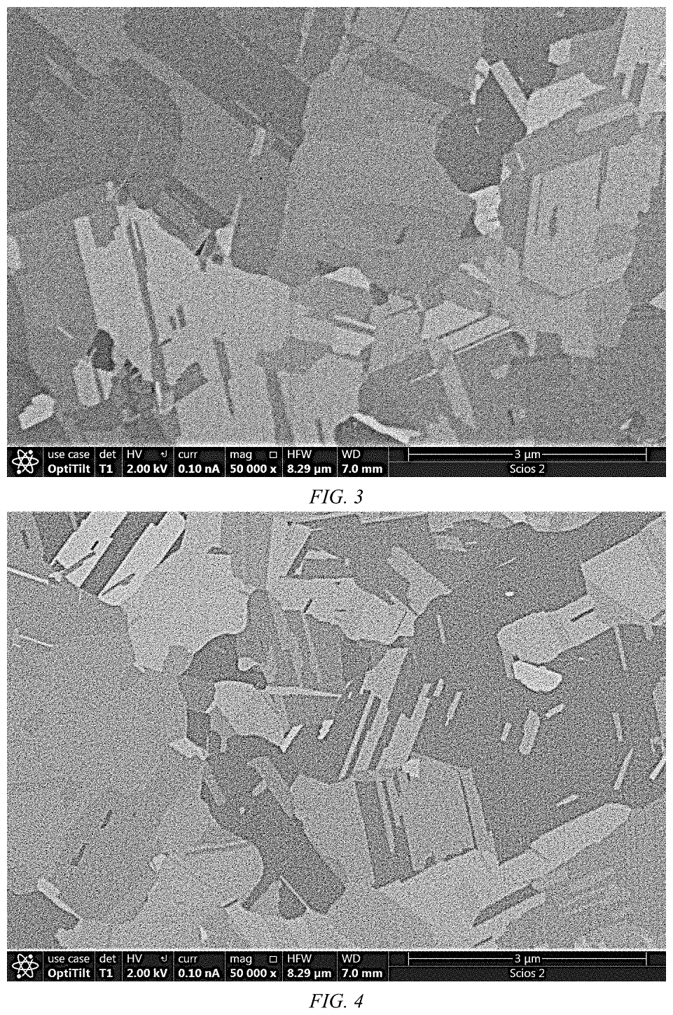

After electroplating, the internal stress was measured by a bent strip test. The conditions are as follows: 2,000 mL beak, 1,800 mL electrolyte, Cu-anodes with bag, 200 rd/min, stirred 40×8 mm, up to 5 A/dm², bent strip immersed 10 mm above single strips, position exact in the middle of the anodes. The internal stress of the electroplated copper film of example 1 measured after electroplating (within one hour), at 24 hours after electroplating or annealed at 60 to 120° C. for 0.5 to 2 hours, and storage (at 72 hour after electroplating or annealing) is shown in FIG. 1. FIG. 3 shows the grain structure of electroplated copper film of example 1. FIG. 5 shows the X-ray diffraction pattern of the electroplated copper film of example 1. FIG. 7 shows the flatness and uniformity of the electroplated copper film of example 1.

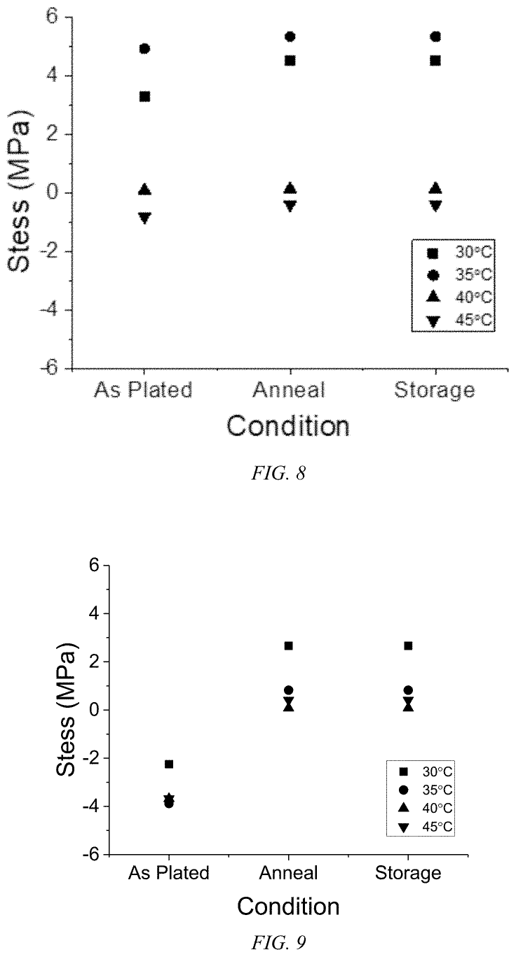

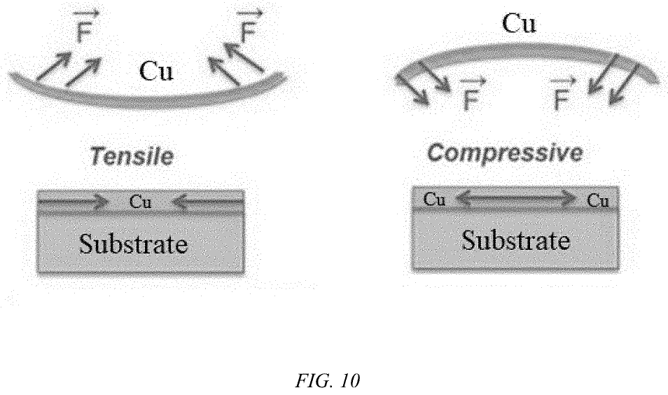

The electroplating was conducted at various temperatures to find the optimal temperature for achieving stress free electroplated copper film. To conduct electroplating at a certain temperature, the electroplating bath was heated to the designed temperature. The electroplating bath was maintained at the designed temperature while conducting the electroplating. The electroplating temperature effect is show in FIG. 8.

The thickness of the stress-free electroplated copper film was measured. The thick is 10 to 50 μm. The resistivity of the stress-free electroplated copper film was also measured. The resistivity is 1.70 to 2.20 μOhM·cm.

The impurity of the electroplated copper film of Example 1 was analyzed by secondary ion mass spectrometry (SIMS). The result is shown in Table 2.

TABLE 2

| Element | C | O | N | S | Cl | Total |
|---|---|---|---|---|---|---|
| ppm | 59 | 10 | 0.1 | 2.3 | 36 | 107.4 |

### Example 2

An electrolytic copper plating composition of the invention was prepared having the following components and concentrations.

The electrolytic copper deposition chemistry and plating conditions were prepared according to the instructions of Table 3 for example 2.

TABLE 3

| Consideration | Example | Range |
|---|---|---|
| Cooper, g/L | 50 | 25 to 75 |
| Sulfuric acid, g/L | 100 | 75 to 125 |
| Chloride, ppm | 50 | 25 to 75 |
| Suppressor, ppm | 500 | 500 to 1500 |
| Leveler, ppm | 15 | 5 to 100 |
| Accelerator, ppm | 10 | 3 to 30 |
| Plating Temperature, ° C. | 40 | 25 to 65 |
| Platine rate, ASD | 5 | 2 to 20 |
| Aeitation speed, RPM | 200 | 100 to 400 |

The chlorine compound is hydrochloric acid. The suppressor is carboxymethylcellulose and its analogue or equivalent. The accelerator is 3-mercapto-1-propane sulfonic acid and its analogue or equivalent. The leveler is

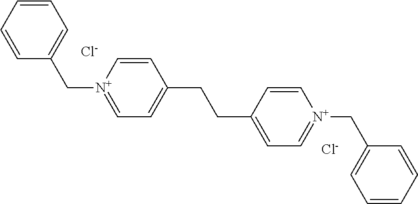 [SMILES: c1ccc(C[n+]2ccc(CCc3cc[n+](Cc4ccccc4)cc3)cc2)cc1 ; [Cl-] ; [Cl-]]

and its analogue or equivalent.

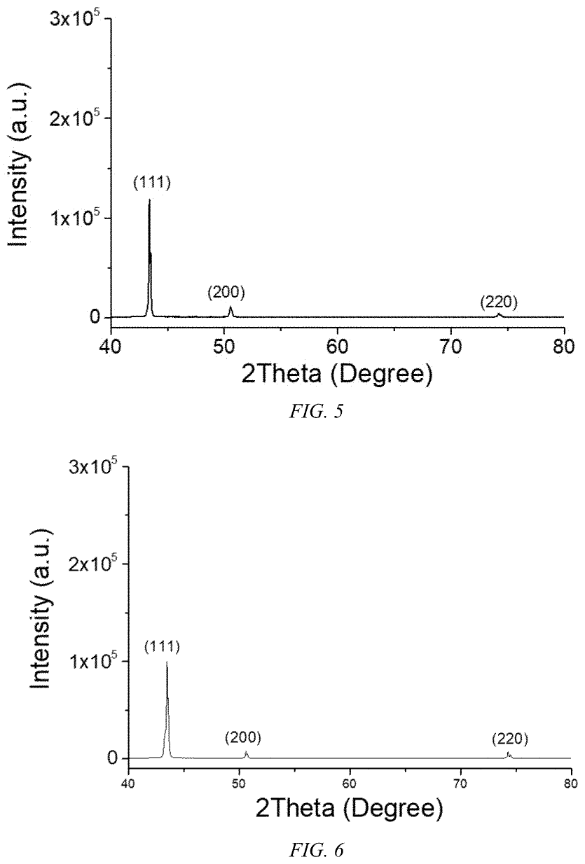

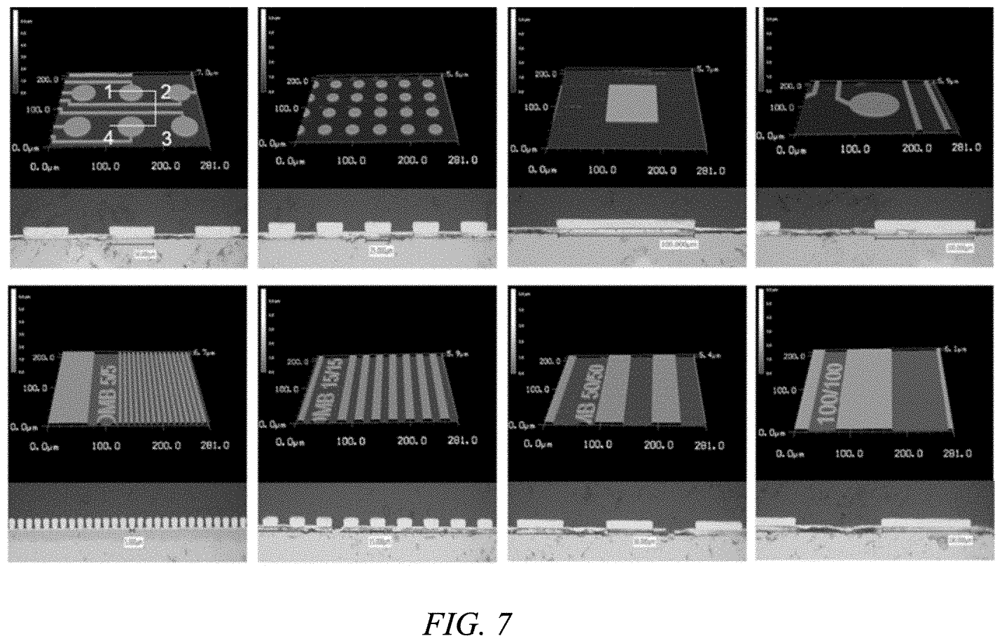

After electroplating, the internal stress was measured by a bent strip test. The internal stress of the electroplated copper film of example 2 measured after electroplating (within one hour), at 24 hours after electroplating or annealed at 60 to 120° C. for 0.5 to 2 hours, and storage (at 72 hours after electroplating or annealing) is shown in FIG. 2. FIG. 4 shows the grain structure of electroplated copper film of example 2. FIG. 6 shows the X-ray diffraction pattern of the electroplated copper film of example 2.

The electroplating was conducted at various temperatures to find the optimal temperature for achieving stress free electroplated copper film. To conduct electroplating at a certain temperature, the electroplating bath was heated to the designed temperature. The electroplating bath was maintained at the designed temperature while conducting the electroplating. The electroplating temperature effect is show in FIG. 9.

The thickness of the stress-free electroplated copper film was measured. The thick is 10 to 50 μm. The resistivity of the stress-free electroplated copper film was also measured. The resistivity is 1.70 to 2.20 μOhM·cm.

The impurity of the electroplated copper film of Example 2 was analyzed by secondary ion mass spectrometry (SIMS). The result is shown in Table 4.

TABLE 4

| Element | C | O | N | S | Cl | Total |
|---|---|---|---|---|---|---|
| ppm | 1.7 | 1.09 | 0.1 | 0.11 | 0.12 | 3.12 |

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. A method of electroplating a stress-free copper film on a substrate comprising:
providing the substrate;
providing an electroplating bath that includes a copper salt, an acid, a leveler, a chlorine compound, an accelerator, a suppressor; and water;
heating the electroplating bath to 25 to 60° C.; and
electroplating the substrate in the electroplating bath to form the stress-free copper film while maintaining the electroplating bath at 25 to 60° C.,
wherein the leveler is an organic compound.

2. The method of claim 1, wherein the electroplating bath is heated to 30 to 55° C., and the electroplating bath is maintained at 30 to 55° C. for the electroplating; the electroplating bath is heated to 35 to 50° C., and the electroplating bath is maintained at 35 to 50° C. for the electroplating; the electroplating bath is heated to 35 to 45° C., and the electroplating bath is maintained at 35 to 45° C. for the electroplating; or the electroplating bath is heated to 40 to 45° C., and the electroplating bath is maintained at 40 to 45° C. for the electroplating.

3. The method of claim 1, wherein the electroplating is conducted at a current density of 2-20 A/dm²; at a current density of 3-15 A/dm²; or at a current density of 5-10 A/dm².

4. The method of claim 1, wherein the copper salt is copper sulfate and has a Cu⁺ concentration of 25-75 g/L; the acid is sulfuric acid and has a concentration of 75-125 g/L; the chlorine compound is hydrochloride and has a Cl⁻ concentration of 25-75 ppm; the accelerator has a concentration of 3-30 mg/L; and the suppressor has a concentration of 500-1500 mg/L; and leveler has a concentration of 5-100 mg/L.

5. The method of claim 4, wherein the accelerator is selected from the group consisting of 3,3′-dithiobis(1-propane-sulfonic acid), 3-mercapto-1-propane sulfonic acid, ethylenedithiodipropyl sulfonic acid, bis-(ω-sulfobutyl)-disulfide, methyl-(ω-sulfopropyl)-disulfide, N,N-dimethyldithiocarbamic acid (3-sulfopropyl) ester, (O-ethyldithiocarbonato)-S-(3-sulfopropyl)-ester, 3-[(amino-iminomethyl)-thiol]-1-propanesulfonic acid, 3-(2-benzylthiazolylthio)-1-propanesulfonic acid, bis-(sulfopropyl)-disulfide, and alkali metal salts thereof.

6. The method of claim 4, wherein the suppressor is selected from the group consisting of polyoxyalkylene glycol, carboxymethylcellulose, nonylphenolpolyglycol ether, octandiolbis-(polyalkylene glycolether), octanolpolyalkylene glycolether, oleic acidpolyglycol ester, polyethylenepropylene glycol, polyethylene glycol, polyethylene glycoldimethylether, polyoxypropylene glycol, polypropylene glycol, polyvinylalcohol, stearic acidpolyglycol ester and stearyl alcoholpolyglycol ether.

7. The method of claim 4, wherein the leveler is selected from the group consisting of 1-(2-hydroxyethyl)-2-imidazolidinethione, 4-mercaptopyridine, 2-mercaptothiazoline, ethylene thiourea, thiourea, alkylated polyalkyleneimine, poly[bis(2-chloroethyl) ether-alt-1,3-bis[3-(dimethylamino)propyl]urea], poly(diallyldimethylammonium chloride), L-2-amino-3-ureidopropionic acid, poly(ethyleneimine),

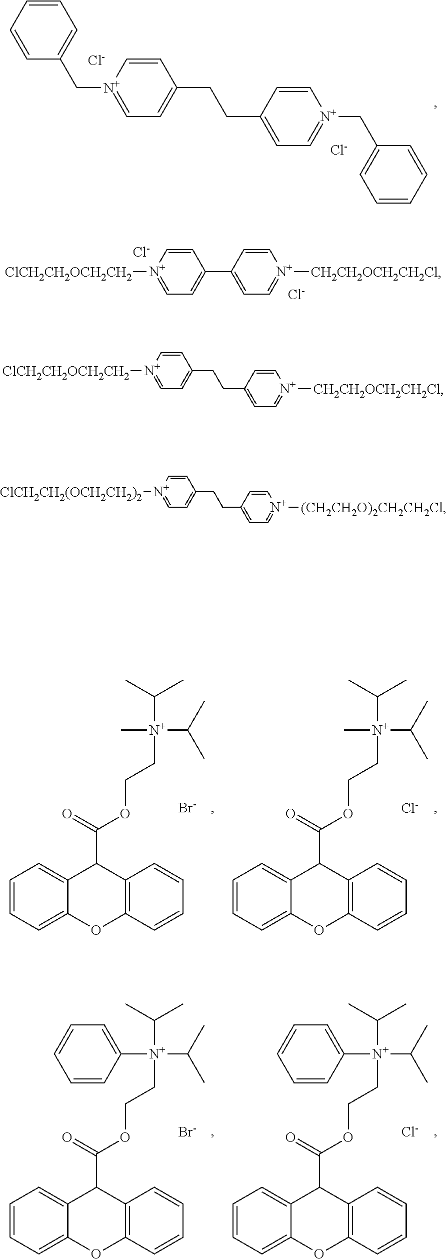

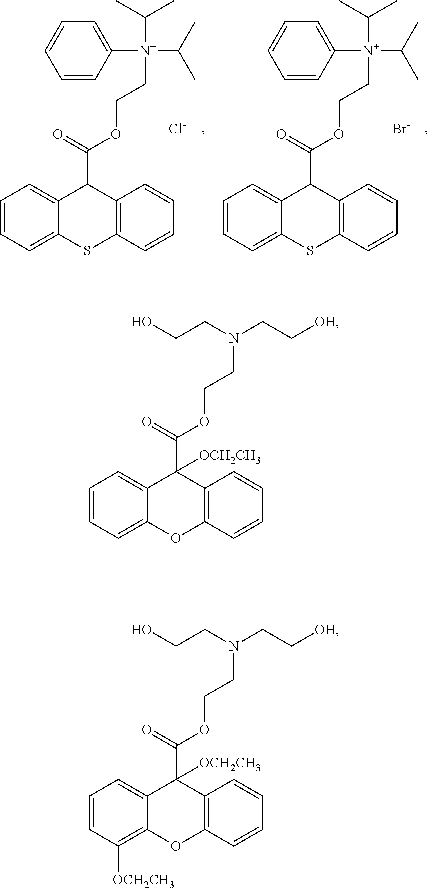 [SMILES: CC(C)[N+](CCOC(=O)C1c2ccccc2Sc2ccccc21)(c1ccccc1)C(C)C ; [Cl-] ; CC(C)[N+](CCOC(=O)C1c2ccccc2Sc2ccccc21)(c1ccccc1)C(C)C ; [Br-] ; CCOC1(C(=O)OCCN(CCO)CCO)c2ccccc2Oc2ccccc21 ; CCOc1cccc2c1Oc1ccccc1C2(OCC)C(=O)OCCN(CCO)CCO]

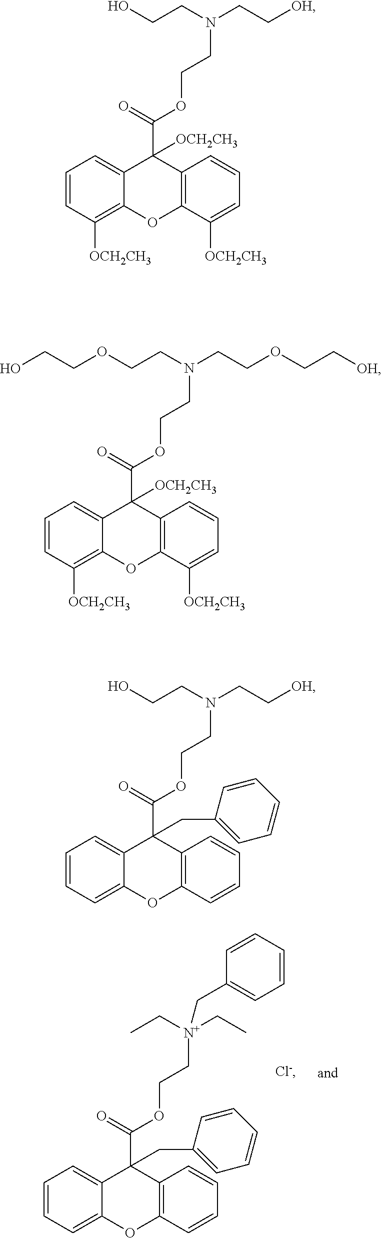 [SMILES: CCOc1cccc2c1Oc1c(OCC)cccc1C2(OCC)C(=O)OCCN(CCO)CCO ; CCOc1cccc2c1Oc1c(OCC)cccc1C2(OCC)C(=O)OCCN(CCOCCO)CCOCCO ; O=C(OCCN(CCO)CCO)C1(Cc2ccccc2)c2ccccc2Oc2ccccc21 ; CC[N+](CC)(CCOC(=O)C1(Cc2ccccc2)c2ccccc2Oc2ccccc21)Cc1ccccc1]

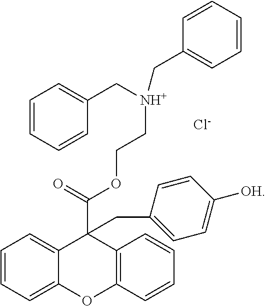 [SMILES: O=C(OCC[NH+](Cc1ccccc1)Cc1ccccc1)C1(Cc2ccc(O)cc2)c2ccccc2Oc2ccccc21 ; [Cl-]]

8. The method of claim 1, further comprising:
annealing the stress-free copper film at 60-260° C. for 0.5 to 2 hours, or at 60-120° C. for 0.5 to 2 hours.

9. The method of claim 1, further comprising:
stirring the electroplating bath at an agitation of 100-1400 rpm or its corresponding double layer thickness while electroplating the substrate in the electroplating bath to form the stress-free copper film.

10. A stress-free electroplated copper film comprising:
a thickness of 2 to 200 μm;
a first internal stress of about −0.08 to 0.20 MPa, the first internal stress being measured within 1 hour after electroplating the stress-free electroplated copper film on a substrate;
a second internal stress of about 0.08 to 0.12 MPa, the second internal stress being measured 24 hours after electroplating or annealed at 60 to 120° C. for 0.5 to 2 hours;
an impurity of 20 to 120 ppm; and
an X-ray powder diffraction pattern having an I(111):I(200):I(220) intensity ratio of about 100:9.5:3.7 or 27:2.5:1.

11. The stress-free electroplated copper film of claim 10, further comprising:
a third internal stress of about 0.08 to 0.12 MPa, the third internal stress being measured 72 hours after electroplating or annealing.

12. A stress-free electroplated copper film comprising:
a thickness of 2 to 200 μm;
a first internal stress of about −4.0 to 4.0 MPa, the first internal stress being measured within 1 hour after electroplating the stress-free electroplated copper film on a substrate;
a second internal stress of about 0.08 to 0.12 MPa, the second internal stress being measured after electroplating and annealed at 60-120° C. for 0.5 to 2 hours;
an impurity of 1 to 4 ppm; and
an X-ray powder diffraction pattern having an I(111):I(200):I(220) intensity ratio of about 100:7:7 or 14.3:1:1.

13. The stress-free electroplated copper film of claim 12, further comprising:
a third internal stress of about 0.08 to 0.12 MPa, the third internal stress being measured 72 hours after annealing.

14. The stress-free electroplated copper film of claim 10, wherein the impurity comprises carbon, oxygen, nitrogen, sulfur, and chlorine.

15. The stress-free electroplated copper film of claim 10, wherein the thickness of the stress-free electroplated copper film is 10 to 50 μm.

16. The stress-free electroplated copper film of claim 10, wherein the stress-free electroplated copper film has a resistivity of 1.70 to 2.20 μOhM·cm.

17. The stress-free electroplated copper film of claim 12, wherein the impurity comprises carbon, oxygen, nitrogen, sulfur, and chlorine.

18. The stress-free electroplated copper film of claim 12, wherein the thickness of the stress-free electroplated copper film is 10 to 50 μm.

19. The stress-free electroplated copper film of claim 12, wherein the stress-free electroplated copper film has a resistivity of 1.70 to 2.20 μOhM·cm.
